(19) United States
(12) Patent Application Publication
(10) Pub. No.: US 2019/0020319 A1
(43) Pub. Date: Jan. 17, 2019

(54) OPTICAL-TO-RADIO CONVERTER

(71) Applicant: NATIONAL INSTITUTE OF INFORMATION AND COMMUNICATIONS TECHNOLOGY, Koganei-shi, Tokyo (JP)

(72) Inventors: Toshimasa UMEZAWA, Tokyo (JP); Kouichi AKAHANE, Tokyo (JP); Atsushi MATSUMOTO, Tokyo (JP); Atsushi KANNO, Tokyo (JP); Naokatsu YAMAMOTO, Tokyo (JP); Tetsuya KAWANISHI, Tokyo (JP)

(73) Assignee: NATIONAL INSTITUTE OF INFORMATION AND COMMUNICATIONS TECHNOLOGY, Koganei-shi, Tokyo (JP)

(21) Appl. No.: 16/069,457

(22) PCT Filed: Jan. 10, 2017
(86) PCT No.: PCT/JP2017/000410

§ 371 Date: Jul. 11, 2018

(30) Foreign Application Priority Data
Jan. 15, 2016 (JP) 2016-006180

(51) Int. Cl. H03F 3/19; H03F 3/08; H03F 1/02; H04B 10/69

(52) U.S. Cl. CPC H03F 3/19; H03F 3/08; H03F 2200/451; H04B 10/69; H03F 1/02

(57) ABSTRACT

There is provided a photoelectric converter that converts an optical signal into an electrical signal for amplification, the photoelectric converter including a photoelectric conversion element that converts the optical signal into an electrical signal and outputs the electrical signal from an output terminal, a high-frequency amplifier that includes an input terminal of an electrical signal output from the output terminal and a DC cut-off capacitor which is disposed at an output stage of the input terminal and is serially connected to the input terminal and that amplifies the electrical signal, and an inductance element that is disposed between a bias power supply applying bias voltage or bias current to the photoelectric conversion element and the input terminal and which is connected in parallel to the DC cut-off capacitor.

### TECHNICAL FIELD

The present invention relates to a Optoelectic converter that converts an optical signal into an electrical signal for amplification, and in particular, to a narrow-band photoelectric converter.

### BACKGROUND ART

The transmission capacity of optical communication systems has been increasing year after year. It is thus necessary to keep increasing the transmission capacity. The optical communication system includes a fixed optical communication system and an optical fiber wireless communication system in which a wireless system is combined with an optical communication system. In the current optical communication system, the fixed optical communication system, which achieves large capacity transmission, has been employed as a core network (a backbone line). For example, assuming applications to a mobile backhaul (a relay line connecting an access line at the end and a backbone network (a backbone line) at the center), an optical fiber wireless technology will become important in the future.

It is commonly believed that increasing a carrier frequency is advantageous to increase the transmission capacity in the optical fiber wireless system. This is because a width of approximately 20% of a center frequency is obtained as a frequency bandwidth. That is, when the center frequency is 10 GHz, the frequency bandwidth is approximately 2 GHz, whereas when the center frequency is 100 GHz, the frequency bandwidth is approximately 20 GHz and thus the frequency bandwidth is increased.

Meanwhile, a key technology in the optical fiber wireless technology is a narrow-band photodetector. The narrow-band photodetector is a photoelectric converter that converts an optical signal having been modulated at a certain frequency into a high-frequency electrical signal. In view of practical application and mass production of this photoelectric converter (hereinafter, “photoreceiver”), it is assumed that stabilization of frequency characteristics and production cost reduction are very important factors.

A photoreceiver has been widely and commonly used in the fixed optical communication system, and is mainly constituted by a photodiode and a high-frequency amplifier (a transimpedance amplifier). Photoreceivers with a frequency band of DC (direct current) to 30 GHz (gigahertz) have been made into products and widely available. On the other hand, products and research report cases of a narrow-band photoreceiver having a high-frequency amplifier with a microwave or millimeter wave frequency band incorporated therein for use in optical fiber wireless applications are few in number. Few reports have been made about the stabilization of frequency characteristics and the production cost reduction. In most cases, a single photodiode module is connected to a single narrow-band (power) amplifier module by an electrical connector.

For example, Non Patent Literature 1 describes an example of externally connecting a photodiode to a high-frequency amplifier. In addition, Non Patent Literature 2 describes methods of connecting a photodiode and a high-frequency amplifier that are commonly used. Non Patent Literature 2 describes an example of operating the photodiode by internal bias drive and an example of operating the photodiode by external bias drive.

### CITATION LIST

### Non Patent Literature

Non Patent Literature 1: S. Babiel, A. Stohr, A. Kanno and T. Kawanishi, “Radio-over-Fiber Photonic Wireless Bridge in the W-Band”, IEEE International conference on Communications 2013, pp. 838-842, Workshop on optical-wireless integrated technology for systems and network 2013
Non Patent Literature 2: 11.3 Gbps Limiting Transimpedance Amplifier With RSSITEXAS Instrument ONET8501T

### SUMMARY OF INVENTION

### Technical Problem

In narrow-band photoreceivers, high outputs and formation of high output lines are important factors, and thus by using a linear amplifier commonly used in a microwave circuit instead of a high-frequency amplifier, good characteristics are easily obtained. The linear amplifier does not include an internal bias circuit for connecting a photodiode, and thus cannot employ a connection method of operating a photodiode by internal bias drive as proposed in Non Patent Literature 2. Meanwhile, connection is possible by a connection method of operating a photodiode by external bias drive, but wire inductance for connection tends to be increased.

When an operating frequency is low, for example, approximately 10 GHz (gigahertz), problems may not occur in frequency characteristics of the entire photoreceiver. However, as the operating frequency is increased (in particular, 30 GHz or higher), the wire inductance affects the frequency characteristics (a bandwidth and flatness). Consequently, wires connecting a photodiode to a high-frequency amplifier are preferably as short as possible in a higher frequency range. Direct current is commonly cut off at an input part of a linear amplifier by a DC cut-off capacitor and thus photocurrent from a photodiode cannot be monitored (a wide-band high-frequency amplifier can be operated with direct current and the input part is designed to have low impedance). This means that optical alignment between the photodiode and an optical fiber is impossible, and makes it difficult to assemble an optical system including the optical fiber.

As described above, conventional photoreceivers have problems that two modules (a photodiode and a high-frequency amplifier) are connected using a connector, and thus a high-frequency loss is generated and photoelectric conversion efficiency is reduced (a power loss is increased) accordingly. In addition, there is a problem that frequency characteristics are inferior. Moreover, there is a problem that as the space for mounting the two modules (the photodiode and the high-frequency amplifier) is needed, the photoreceiver is increased in size and a compact transmission and reception experimental device is difficult to be designed. Further, there is a problem that it is necessary to separately purchase the two modules (the photodiode and the high-frequency amplifier), and thus the production cost is increased.

The present invention has been achieved in view of the problems, and an object of the invention is to provide a photoelectric converter that has a low power loss and good frequency characteristics.

### Solution to Problem

A photoelectric converter according to the present invention is a photoelectric converter that converts an optical signal into an electrical signal for amplification. The photoelectric converter includes a photoelectric conversion element that converts the optical signal into an electrical signal and outputs the electrical signal from an output terminal, a high-frequency amplifier that includes an input terminal of an electrical signal output from the output terminal and a DC cut-off capacitor which is disposed at an output stage of the input terminal and is serially connected to the input terminal and that amplifies the electrical signal, and an inductance element that is disposed between a bias power supply applying bias voltage or bias current to the photoelectric conversion element and the input terminal and that is connected in parallel to the DC cut-off capacitor.

According to the configuration described above, the high-frequency amplifier includes the DC cut-off capacitor serially connected to the input terminal, and the inductance element that is disposed between the bias power supply applying bias voltage or bias current to the photoelectric conversion element and the input terminal and that is connected in parallel to the DC cut-off capacitor. Externally supplied his voltage or bias current is thus applied to the photoelectric conversion element without flowing into the high-frequency amplifier. In addition, a high-frequency signal generated by the photoelectric conversion element is cut off (blocked) by the inductance element to flow into the high-frequency amplifier without flowing into a side of the bias. A photodiode can thus be operated by external bias drive. Further, a power loss is low and frequency characteristics are good.

In the photoelectric converter according to the present invention, an output terminal of the photoelectric conversion element is connected to an input terminal of the high-frequency amplifier by a bump for flip-chip mounting, a bonding wire, or a through-electrode.

According to the configuration described above, the output terminal of the photoelectric conversion element is connected to the input terminal of the high-frequency amplifier by a bump for flip-chip mounting, a bonding wire, or a through-electrode. Inductance between the output terminal of the photoelectric conversion element and the input terminal of the high-frequency amplifier can thus be reduced, and a power loss can be effectively reduced. Further, frequency characteristics are good. In addition, the configuration described above can reduce the number of components and the number of assembly steps of the photoelectric converter. As a result, it is possible to reduce the manufacturing cost of the photoelectric converter (a photoreceiver module).

In the photoelectric converter according to the present invention, inductance between the output terminal of the photoelectric conversion element and the input terminal of the high-frequency amplifier is 500 pH or less.

According to the configuration described above, the inductance between the output terminal of the photoelectric conversion element and the input terminal of the high-frequency amplifier is 500 pH or less, and thus a power loss is much lower and good frequency characteristics are effectively achieved.

The high-frequency amplifier of the photoelectric converter according to the present invention amplifies a certain band in a band of 30 GHz (gigahertz) or higher.

According to the configuration described above, the high-frequency amplifier amplifies a certain band in a band of 30 GHz (gigahertz) or higher. The high-frequency amplifier is used for a band of 30 GHz (gigahertz) or higher where frequency characteristics are easily degraded. It is thus possible to improve frequency characteristics more effectively.

In the photoelectric converter according to the present invention, electrostatic capacity of the capacitor is 1 pF (picofarad) to a few hundred pF (picofarad), and inductance of the inductance element is 0.2 nH (nanohenry) or larger.

According to the configuration described above, the electrostatic capacity of the capacitor is 1 pF (picofarad) to a few hundred pF (picofarad), and the inductance of the inductance element is 0.2 nH (nanohenry) or larger. It is thus possible to effectively prevent bias from flowing into a side of the high-frequency amplifier. In addition, it is also possible to effectively prevent a high-frequency signal generated by a photoelectric conversion element from flowing into a bias side.

### Advantageous Effects of Invention

The present invention can provide a photoelectric converter that has a low power loss and good frequency characteristics.

### BRIEF DESCRIPTION OF DRAWINGS

FIG. 1 is a circuit diagram of a photoelectric converter according to an embodiment.

FIG. 2 is a configuration diagram showing a connection method of the photoelectric converter according to the embodiment.

FIG. 3 shows simulation results of frequency characteristics of a photoelectric converter according to an example.

FIG. 4 shows simulation results of transmission characteristics of the photoelectric converter according to the example.

FIG. 5 shows results of the transmission characteristics in an actual device of the photoelectric converter according to the example and in simulation.

FIG. 6 is a circuit diagram of a photoelectric converter according to a comparative example.

FIG. 7 is another circuit diagram of the photoelectric converter according to the comparative example.

### DESCRIPTION OF EMBODIMENTS

### Embodiment

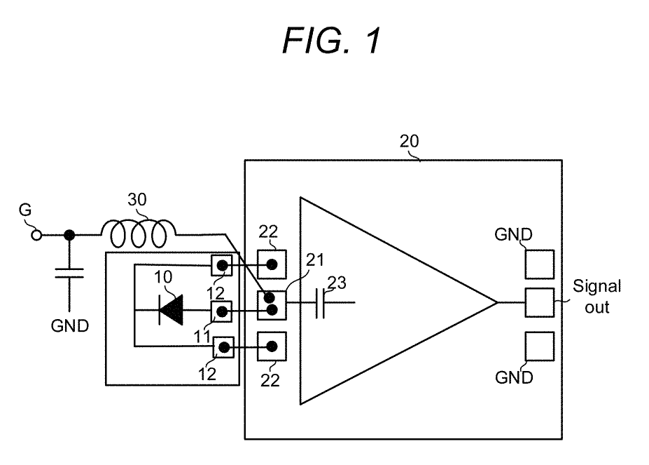

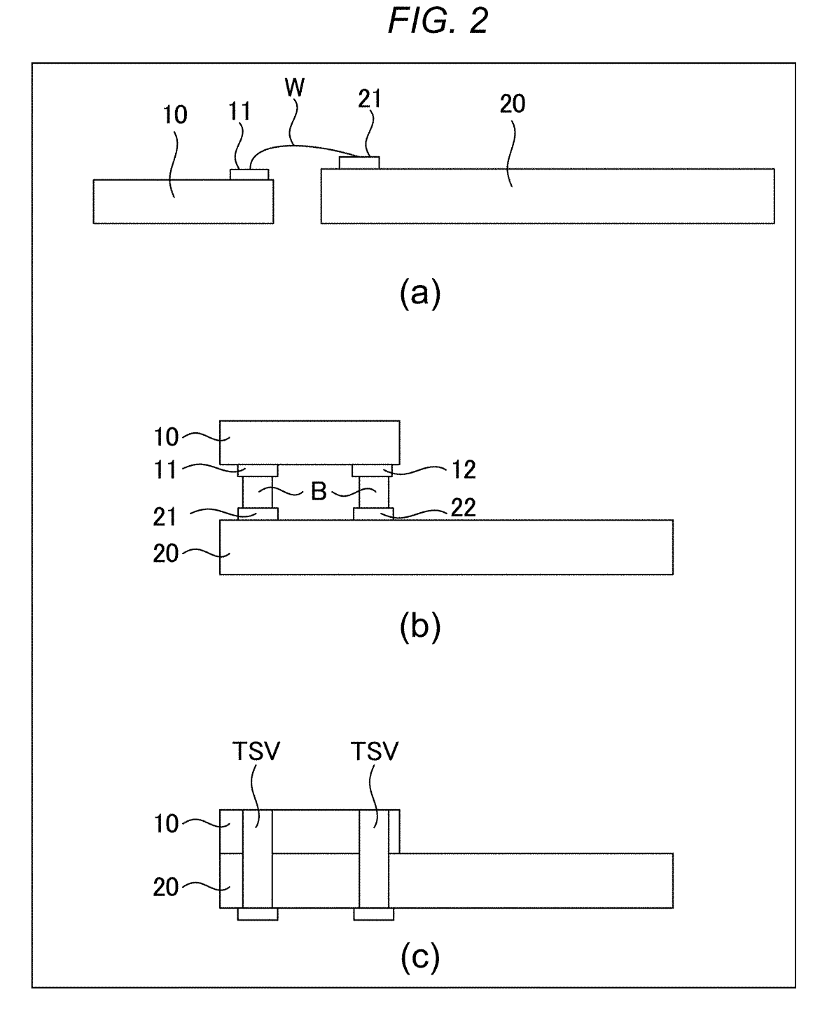

FIG. 1 is a circuit diagram of a photoelectric converter according to an embodiment. FIG. 2 is a configuration diagram showing a connection method of the photoelectric converter according to the embodiment. A configuration of the photoelectric converter according to the present embodiment is described below with reference to FIGS. 1 and 2.

As shown in FIG. 1, the photoelectric converter (a photoreceiver) according to the present embodiment includes a photoelectric conversion element 10, a high-frequency amplifier 20, and an inductance element 30. The photoelectric conversion element 10 is, for example, a photodiode, converts an optical signal into an electrical signal, and outputs the electrical signal from an output terminal 11. The photoelectric conversion element 10 also includes a ground terminal (GND) 12, in addition to the output terminal 11.

The high-frequency amplifier 20 is, for example, a linear amplifier, and amplifiers an electrical signal output from the output terminal 11 of the photoelectric conversion element 10. The high-frequency amplifier 20 is a narrow-band amplifier that amplifies a certain band in a band of 30 GHz (gigahertz) or higher.

The high-frequency amplifier 20 includes an input terminal 21 to which an electrical signal from the photoelectric conversion element 10 is input, a ground terminal (GNU) 22, and a DC cut-off capacitor 23 that is disposed at the output stage of the input terminal 21 and is serially connected to the input terminal 21. It is designed in the present embodiment that the electrostatic capacity of the DC cut-off capacitor 23 is 1 pF (picofarad) to a few hundred pF (picofarad).

The inductance element 30 is disposed between a bias power supply G that applies bias voltage or bias current to the photoelectric conversion element 10 and the input terminal 21 of the high-frequency amplifier 20, and is connected in parallel to the DC cut-off capacitor 23. It is designed in the present embodiment that the inductance of the inductance element 30 is 0.2 nH (nanohenry) or larger.

The inductance between the output terminal 11 of the photoelectric conversion element 10 and the input terminal 21 of the high-frequency amplifier 20 is preferably 500 pH or less. As the inductance between the output terminal 11 of the photoelectric conversion element 10 and the input terminal 71 of the high-frequency amplifier 20 is 500 pH or less, frequency characteristics when a signal in a high-frequency band, in particular, a high-frequency band of 30 GHz (gigahertz) or higher is amplified are improved.

As shown in FIG. 2, the photoelectric conversion element 10 is connected to the high-frequency amplifier 20 by flip-chip mounting, wire bonding, or through-electrodes. FIG. 2(a) shows an example of connecting a semiconductor chip having a circuit of the photoelectric conversion element 10 formed thereon to a semiconductor chip having a circuit of the high-frequency amplifier 20 formed thereon by wire bonding. In the examples shown in FIG. 2(a), the output terminal 11 of the photoelectric conversion element 10 is connected to the input terminal 21 of the high-frequency amplifier 20 by a bonding wire W, and the ground terminal 12 of the photoelectric conversion element 10 is connected to the ground terminal 22 of the high-frequency amplifier 20 by the bonding wire W. In the example shown in FIG. 2(a), the inductance element 30 is achieved by the bonding wire W, and inductance is adjusted based on the length and loop shape of the bonding wire W or the like.

Alternatively, the semiconductor chip having the circuit of the photoelectric conversion element 10 formed thereon may be stacked via a spacer on the semiconductor chip having the circuit of the high-frequency amplifier 20 formed thereon. Thereafter, the output terminal 11 of the photoelectric conversion element 10 may be connected to the input terminal 21 of the high-frequency amplifier 20 by the bonding wire W, and the ground terminal 12 of the photoelectric conversion element 10 may be connected to the ground terminal 22 of the high-frequency amplifier 20 by the bonding wire W.

FIG. 2(b) shows an example of connecting a semiconductor chip having a circuit of the photoelectric conversion element 10 formed thereon to a semiconductor chip having a circuit of the high-frequency amplifier 20 formed thereon by flip-chip connection. In the example shown in FIG. 2(b), the output terminal 11 of the photoelectric conversion element 10 is connected to the input terminal 21 of the high-frequency amplifier 20 by a bump B, and the ground terminal 12 of the photoelectric conversion element 10 is connected to the ground terminal 22 of the high-frequency amplifier 20 by the bump B. In the example shown in FIG. 2(b), the inductance element 30 is achieved by the bump B, and inductance is adjusted based on the shape of the bump B or the like.

FIG. 2(c) shows an example of connecting a semiconductor chip having a circuit of the photoelectric conversion element 10 formed thereon to a semiconductor chip having a circuit of the high-frequency amplifier 20 formed thereon by a Si through-electrode TSV. In the example shown in FIG. 2(c), the output terminal 11 of the photoelectric conversion element 10 is connected to the input terminal 21 of the high-frequency amplifier 20 by the Si through-electrode TSV, and the ground terminal 12 of the photoelectric conversion element 10 is connected to the ground terminal 22 of the high-frequency amplifier 20 by the Si through-electrode TSV. In the example shown in FIG. 2(c), the inductance element 30 is achieved by the Si through-electrode TSV, and inductance is adjusted based on the length and shape of the Si through-electrode TSV or the like.

As described with reference to FIG. 2, the photoelectric conversion element 10 is connected to the high-frequency amplifier 20 by any of flip-chip mounting, wire bonding, and through-electrodes, and thus the inductance between the output terminal 11 of the photoelectric conversion element 10 and the input terminal 21 of the high-frequency amplifier 20 can be 500 pH or less and frequency characteristics in amplification are improved. In addition, the configuration shown in FIG. 2 can reduce the number of components and the number of assembly steps of a photoelectric converter. As a result, it is possible to reduce the manufacturing cost of the photoelectric converter (a photoreceiver module).

### EXAMPLE

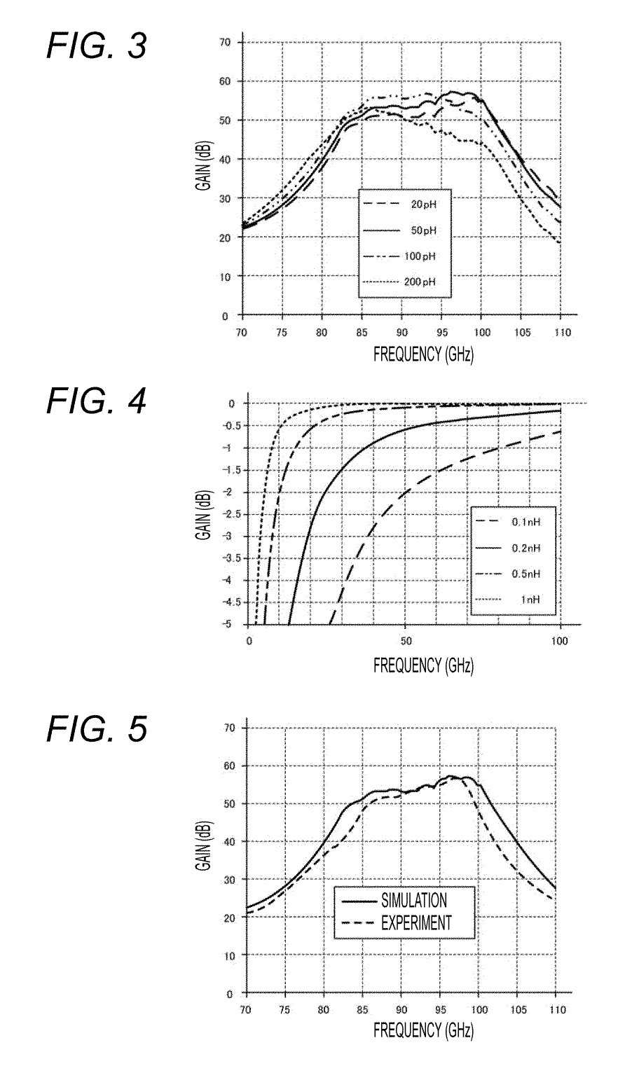

FIG. 3 shows simulation results of frequency characteristics of the photoelectric converter described with reference to FIG. 1. FIG. 4 shows simulation results of transmission characteristics between the photoelectric conversion element 10 and the high-frequency amplifier 20 in the photoelectric converter described with reference to FIG. 1. FIG. 5 shows results of the transmission characteristics in an actual device of the photoelectric converter described with reference to FIG. 1 according to the embodiment and in simulation.

FIG. 3 shows simulation results obtained when actual measurement values (S parameters) in a frequency band of 90 GHz to 100 GHz are used for the high-frequency amplifier 20 and a photodiode functioning as the photoelectric conversion element 10 is connected to the high-frequency amplifier 20. The horizontal axis in FIG. 3 represents a frequency (GHz) whereas the vertical axis in FIG. 3 represents the gain (dB) of the photoelectric conversion element 10 and the high-frequency amplifier 20.

FIG. 3 shows simulation results obtained when connection inductance of the photoelectric conversion element 10 and the high-frequency amplifier 20 is 20 pH (picohenry), 50 pH, 100 pH, and 200 pH. It is found from the simulation results of FIG. 3 that when the connection inductance of the photoelectric conversion element 10 and the high-frequency amplifier 20 is low, for example, 20 pH and 50 pH, a change in gain relative to a change in frequency is small and flat, and good frequency characteristics are obtained. Further, it is found from the simulation results of FIG. 3 that when the connection inductance of the photoelectric conversion element 10 and the high-frequency amplifier 20 is high, for example, 100 pH and 200 pH, the change in gain relative to the change in frequency is large, and the frequency characteristics are degraded (specifically, the gain is reduced on a high-frequency side). That is, it is found from the simulation results of FIG. 3 that the connection inductance of the photoelectric conversion element 10 and the high-frequency amplifier 20 is preferably low.

In the simulation results of FIG. 3, when the connection inductance of the photoelectric conversion element 10 and the high-frequency amplifier 20 is low, for example, 20 pH and 50 pH, the change in gain relative to the change in frequency is small and flat, and good frequency characteristics are obtained. However, the optimal value of the inductance between the output terminal 11 of the photoelectric conversion element 10 and the input terminal 21 of the high-frequency amplifier 20 varies depending on device parameters and frequency bands on a side of the photoelectric conversion element 10 and thus is preferably 500 pH or less.

FIG. 4 shows simulation results obtained when the inductance of the inductance element 30 is 0.1 nH (nanohenry), 0.2 nH, 0.5 nH, and 1 nH. The simulation results of FIG. 4 show frequency characteristics between the input terminal 21 of the high-frequency amplifier 20 and the bias power supply G in FIG. 1. The horizontal axis in FIG. 4 represents a frequency (GHz) whereas the vertical axis in FIG. 4 represents a transmission loss (dB).

It is found from the simulation results of FIG. 4 that as the inductance of the inductance element 30 is smaller, the transmission loss is larger, and when the inductance of the inductance element 30 is 0.2 nH, the transmission loss is rapidly reduced. In particular, in a frequency band of 30 GHz or higher, when the inductance of the inductance element 30 is 0.1 nH, the transmission loss is −4.5 db, whereas when the inductance of the inductance element 30 is 0.2 nH, the transmission loss is −1.5 db, which is rapidly improved. It is thus found that to reduce the transmission loss in the frequency band of 30 GHz or higher, the inductance of the inductance element 30 is preferably 0.2 nH or larger. In addition, it is found from the results of FIG. 4 that in the frequency band of 30 GHz or higher, when the inductance of the inductance element 30 is 1 nH, substantially no transmission loss is present (the transmission loss is substantially zero). It is thus found that the inductance of the inductance element 30 is more preferably 1 nH or larger.

FIG. 5 shows results of transmission characteristics in an actual device of the photoelectric converter described with reference to FIG. 1 according to the embodiment and in simulation. The horizontal axis in FIG. 5 represents a frequency (GHz) whereas the vertical axis in FIG. 5 represents the gain (dB) of the photoelectric conversion element 10 and the high-frequency amplifier 20. In the actual device of the photoelectric converter shown in FIG. 5, the photoelectric conversion element 10 is connected to the high-frequency amplifier 20 by wire bonding and connection inductance is adjusted to 50 pH (picohenry).

As shown in FIG. 5, also in the actual device, a change in gain relative to a change in frequency is small and flat, and excellent frequency characteristics are obtained. In particular, it is detected from the simulation results of FIG. 3 that in a W band (a band of 75 GHz to 110 GHz), when the inductance (L) of a bonding wire connecting the photoelectric conversion element 10 (the photodiode) to the high-frequency amplifier 20 (the amplifier) is large, the frequency characteristics are significantly degraded.

However, it is detected from the experimental example of the actual device shown in FIG. 5 that only a small influence of the degradation is exerted and the experimental result of the actual device closely matches the simulation result. This is assumed to be a significant effect of this mounting method. Moreover, in hybrid integration in which a semiconductor chip having a circuit of the photoelectric conversion element 10 formed thereon is connected to a semiconductor chip having a circuit of the high-frequency amplifier 20 formed thereon by methods including flip-chip mounting, wire bonding, and through-electrodes as shown in FIG. 2, a connection loss can be kept low as compared to a case of connecting a single module of the photoelectric conversion element 10 (the photodiode) to a single module of the high-frequency amplifier 20 (the amplifier). Consequently, photoelectric conversion can be performed with high efficiency, and it contributes to cost reduction in manufacturing the photoelectric converter (the photoreceiver).

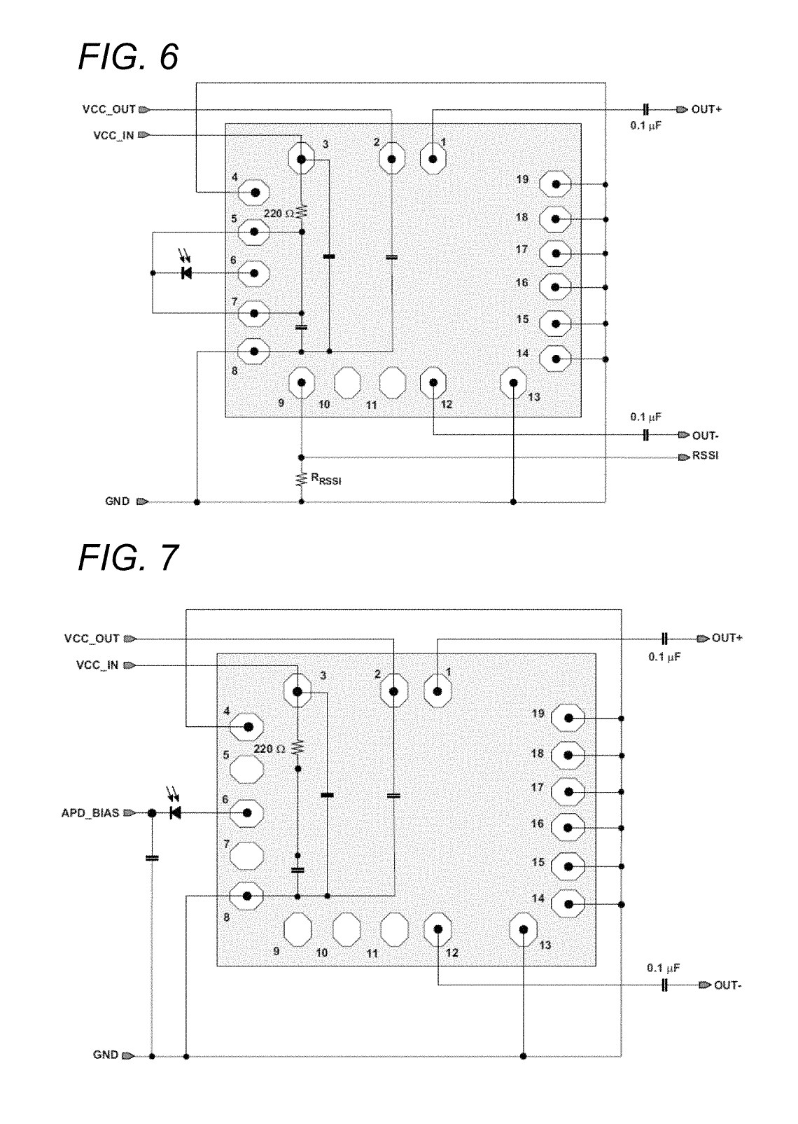

FIGS. 6 and 7 are circuit diagrams of a photoelectric converter according to a comparative example. FIGS. 6 and 7 are circuit diagrams showing connection of a photoelectric conversion element (a photodiode) and a high-frequency amplifier (an amplifier) that are commonly used. FIGS. 6 and 7 are circuit diagrams in which a photoelectric conversion element (a photodiode) is connected to a transimpedance amplifier (TIA).

FIG. 6 is a circuit diagram in a case of internal bias drive. The transimpedance amplifier (TIA) is designed to be connected to the photoelectric conversion element (the photodiode), and thus by connecting a GSG electrode of the photoelectric conversion element (the photodiode) to the transimpedance amplifier (TIA), current (photocurrent) from the photoelectric conversion element can be monitored (measured). In FIG. 6, the photoelectric conversion element (the photodiode) is operated by the transimpedance amplifier (TIA) through internal bias drive. In the comparative example of FIG. 6, the photocurrent from the photoelectric conversion element (the photodiode) can be monitored (measured) by RSSI. FIG. 7 is a circuit diagram in a case of external bias drive, and an operation is performed in which an ammeter and a power supply bias are added to APD Bias.

Meanwhile, in a narrow-band photoreceiver, which is the photoelectric converter of the present embodiment, high outputs and formation of high output lines are important factors, and thus a linear amplifier commonly used in a microwave circuit is used instead of a transimpedance amplifier. As the linear amplifier does not include an internal bias circuit for connecting a photoelectric conversion element (a photodiode), it is impossible to perform the internal bias drive shown in FIG. 6.

Consequently, the connection must be performed by the external bias drive shown in FIG. 7. In this case, however, wires (wiring) used for connecting the photoelectric conversion element (the photodiode) to a high-frequency amplifier (the linear amplifier) become long and thus inductance tends to be increased. When an operating frequency is low, for example, approximately 10 GHz (gigahertz), problems may not occur in frequency characteristics of the entire photoelectric converter (the entire photoreceiver).

However, as the operating frequency is increased (in particular, in a frequency band of 30 GHz or higher), the inductance of wires (wiring) connecting the photoelectric conversion element (the photodiode) to the high-frequency amplifier (the linear amplifier) affects the frequency characteristics (a bandwidth and flatness). Consequently, connection of the photoelectric conversion element (the photodiode) to the high-frequency amplifier (the linear amplifier) is preferably as short as possible. However, wires (wiring) connecting the photoelectric conversion element (the photodiode) to the high-frequency amplifier (the linear amplifier) are long in a conventional connection method, and thus the inductance affects the frequency characteristics.

DC current is commonly cut off at an input part of the linear amplifier based on capacity and photocurrent from the photoelectric conversion element (the photodiode) cannot be monitored (measured). Optical alignment of the photoelectric conversion element (the photodiode) and an optical fiber thus cannot be performed, thus making it difficult to assemble an optical system including the optical fiber.

Meanwhile, in the photoelectric converter according to the present embodiment, a semiconductor chip having a circuit of the photoelectric conversion element 10 formed thereon is connected to a semiconductor chip having a circuit of the high-frequency amplifier 20 formed thereon by any of flip-chip mounting, wire bonding, and through-electrodes. Inductance between the output terminal 11 of the photoelectric conversion element 10 and the input terminal 21 of the high-frequency amplifier 20 can thus be reduced, specifically, 500 pH (picohenry) or less. It is thus possible to achieve a photoelectric converter that can effectively reduce a power loss and at the same time, has good frequency characteristics. In addition, the configuration described above can reduce the number of components and the number of assembly steps of the photoelectric converter. As a result, it is possible to reduce the manufacturing cost of the photoelectric converter (a photoreceiver module).

As described above, the photoelectric converter according to the present embodiment is a photoelectric converter that converts an optical signal into an electrical signal for amplification. The photoelectric converter includes the photoelectric conversion element 10 that converts an optical signal into an electrical signal and outputs the electrical signal from the output terminal 11, the high-frequency amplifier 20 that includes the input terminal 21 of an electrical signal output from the output terminal 11 and the DC cut-off capacitor 23 which is disposed at the output stage of the input terminal 21 and is serially connected to the input terminal 21 and that amplifies an electrical signal, and the inductance element 30 which is disposed between the bias power supply G applying bias voltage or bias current to the photoelectric conversion element 10 and the input terminal 21 and which is connected in parallel to the DC cut-off capacitor 23.

In the photoelectric converter according to the present embodiment, externally supplied bias voltage or bias current is cut off by the DC cut-off capacitor 23 to be applied to the photoelectric conversion element 10 without flowing into the high-frequency amplifier 20. In addition, an electrical signal (a high-frequency signal) generated by the photoelectric conversion element 10 is cut off (blocked) by an inductance element to flow into the high-frequency amplifier 20 without flowing into a side of the bias power supply G. The photoelectric conversion element 10 can thus be operated by external bias drive, and it is possible to achieve a photoelectric converter that has a low power loss and good frequency characteristics.

In the photoelectric converter according to the present embodiment, a semiconductor chip having a circuit of the photoelectric conversion element 10 formed thereon is connected to a semiconductor chip having a circuit of the high-frequency amplifier 20 formed thereon by any of a bump for flip-chip mounting, bonding wires, and through-electrodes. Impedance between the output terminal 11 of the photoelectric conversion element 10 and the input terminal 21 of the high-frequency amplifier 20 can thus be reduced, specifically, 500 pH (picohenry) or less. It is thus possible to achieve a photoelectric converter that can effectively reduce a power loss and at the same time, has good frequency characteristics. In addition, the configuration described above can reduce the number of components and the number of assembly steps of the photoelectric converter. As a result, it is possible to reduce the manufacturing cost of the photoelectric converter (a photoreceiver module).

Moreover, the high-frequency amplifier 20 of the photoelectric converter according to the present embodiment is a narrow-band amplifier that amplifies a certain band in a band of 30 GHz (gigahertz) or higher. That is, the photoelectric converter according to the present embodiment is used for amplification of a band of 30 GHz (gigahertz) or higher where frequency characteristics are easily degraded. It is thus possible to achieve a photoelectric converter that can effectively reduce a power loss and at the same time, has good frequency characteristics.

In the photoelectric converter according to the present embodiment, the electrostatic capacity of the DC cut-off capacitor 23 is 1 pF (picofarad) to a few hundred pF (picofarad), and the inductance of the inductance element 30 is 0.2 nH (nanohenry) or larger. Consequently, it is possible to effectively prevent bias from the bias power supply G from flowing into a side of the high-frequency amplifier 20. Further, it is possible to effectively prevent an electrical signal (a high-frequency signal) generated by the photoelectric conversion element 10 from flowing into the side of the bias power supply G.

### Other Embodiments

The present invention is not limited to the embodiment described above. That is, various changes, combinations, sub-combinations, and substitutions may be made to constituent elements of the embodiment described above by a person skilled in the art within the technical scope of the present invention and the equivalent scope thereof. While the embodiment has described, for example, connection of the photoelectric conversion element 10 (a photodiode) and the high-frequency amplifier 20 (an amplifier), a similar manufacturing method (a similar connection method) may be applied to the photoelectric conversion element 10 (the photodiode).

### REFERENCE SIGNS LIST

10 photoelectric conversion element
11 output terminal
12 ground terminal (GND)
20 high-frequency amplifier
21 input terminal
22 ground terminal (GND)
23 DC cut-off capacitor
30 inductance element
B bump
G power supply
W bonding wire
TSV Si through-electrode

### FIG. 3

GAIN (dB)
FREQUENCY (GHz)

### FIG. 4

GAIN (dB)
FREQUENCY (GHz)

### FIG. 5

GAIN (dB)
FREQUENCY (GHz)
SIMULATION
EXPERIMENT

1. An optical-to-radio converter that converts an optical signal into an electrical signal for amplification, the optical-to-radio converter comprising:
an opto-electric conversion element that converts the optical signal into an electrical signal and outputs the electrical signal from an output terminal;
a high-frequency amplifier that includes an input terminal of an electrical signal output from the output terminal and a DC cut-off capacitor which is disposed at an output stage of the input terminal and is serially connected to the input terminal and that amplifies the electrical signal; and
an inductance element that is disposed between a bias power supply applying bias voltage or bias current to the opto-electric conversion element and the input terminal and that is connected in parallel to the DC cut-off capacitor.

2. The optical-to-radio converter according to claim 1, wherein the output terminal of the opto-electric conversion element is connected to the input terminal of the high-frequency amplifier by any of a bump for flip-chip mounting, a bonding wire, and a through-electrode.

3. The optical-to-radio converter according to claim 2, wherein inductance between the output terminal of the opto-electric conversion element and the input terminal of the high-frequency amplifier is at most 500 pH.

4. The optical-to-radio converter according to claim 1, wherein the high-frequency amplifier amplifies a certain band in a band of at least 30 GHz (gigahertz).

5. The optical-to-radio converter according to claim 1, wherein:
electrostatic capacity of the DC cut-off capacitor is 1 pF (picofarad) to a few hundred pF (picofarad), and
inductance of the inductance element is at least 0.2 nH (nanohenry).

6. The optical-to-radio converter according to claim 2, wherein the high-frequency amplifier amplifies a certain band in a band of at least 30 GHz (gigahertz).

7. The optical-to-radio converter according to claim 3, wherein the high-frequency amplifier amplifies a certain band in a band of at least 30 GHz (gigahertz).

8. The optical-to-radio converter according to claim 2, wherein:
electrostatic capacity of the DC cut-off capacitor is 1 pF (picofarad) to a few hundred pF (picofarad), and
inductance of the inductance element is at least 0.2 nH (nanohenry).

9. The optical-to-radio converter according to claim 3, wherein:
electrostatic capacity of the DC cut-off capacitor is 1 pF (picofarad) to a few hundred pF (picofarad), and
inductance of the inductance element is at least 0.2 nH (nanohenry).

10. The optical-to-radio converter according to claim 4, wherein:
electrostatic capacity of the DC cut-off capacitor is 1 pF (picofarad) to a few hundred pF (picofarad), and
inductance of the inductance element is at least 0.2 nH (nanohenry).

11. The optical-to-radio converter according to claim 6, wherein:
electrostatic capacity of the DC cut-off capacitor is 1 pF (picofarad) to a few hundred pF (picofarad), and
inductance of the inductance element is at least 0.2 nH (nanohenry).

12. The optical-to-radio converter according to claim 7, wherein:
electrostatic capacity of the DC cut-off capacitor is 1 pF (picofarad) to a few hundred pF (picofarad), and
inductance of the inductance element is at least 0.2 nH (nanohenry).
